(19) United States
(12) Patent Application Publication
(10) Pub. No.: US 2005/0153216 A1
(43) Pub. Date: Jul. 14, 2005

(54) Lithography mask and lithography system for direction-dependent exposure

(76) Inventors: Christian Crell, Dresden (DE); Lothar Bauch, Dresden (DE); Holger Moller, Dresden (DE); Ralf Ziebold, Radebeul (DE)

Correspondence Address: SLATER & MATSIL LLP, 17950 PRESTON ROAD, SUITE 1000, DALLAS, TX, 75252, US

(21) Appl. No.: 10/998,300

(22) Filed: Nov. 26, 2004

(30) Foreign Application Priority Data
Nov. 28, 2003 (DE) 103 56 699.6

(51) Int. Cl. G03F 9/00; G03B 27/42

(52) U.S. Cl. 430/5; 355/53

(57) ABSTRACT

Lithography mask having a structure for the fabrication of semiconductor components, in particular memory components, for a direction-dependent exposure device, featuring at least one auxiliary structure (1) for minimizing scattered light, the auxiliary structure (1) essentially being arranged in a low-resolution exposure direction of the direction-dependent exposure device (11, 11a, 11b) for the mask (10, 10a, 10b). A means for reducing scattered light is thus created by the auxiliary structure in a simple manner.

This application claims priority to German Patent Application No. 103 56 699.6, filed on Nov. 28, 2003, which application is hereby incorporated herein by reference.

### TECHNICAL FIELD

The present invention relates generally to a lithography system and method, and more particularly to a lithography mask and lithography system for direction-dependent exposure.

### BACKGROUND

In lithographic methods in semiconductor fabrication, in particular in the fabrication of memory components, the need to fabricate ever smaller structures on a wafer has existed for many years.

In this case, lithographic methods generally use masks which have quartz substrates with absorbent layers. These absorbent layers may be, e.g., light-opaque chromium layers or else partly transmissive absorber layers, e.g., made of molybdenum silicon oxynitride.

The absorbent layer on the mask is patterned such that a pattern is projected onto the wafer during an exposure of the mask. Via the pattern, the structure of the mask is transferred into a light-sensitive layer on the wafer (e.g., a photoresist). This is repeated for many planes on the wafer with different masks.

In order to be able to fabricate ever smaller structures on the wafers, resolution enhancement techniques (RET) have been developed for masks (see e.g., Schellenberg, IEEE Spectrum, September 2003, pp. 34 to 39, which is incorporated herein by reference), which permit the fabrication of very small structures precisely even as exposure wavelengths become ever shorter. These techniques include optimal proximity correction (OPC), phase-shift masks, off-axis exposure and multipole exposure.

In this case, OPC aims to vary the lateral structure dimensions on the mask in order to correct the imaging properties of the projection system including the resist.

Phase-shift masks utilize interference effects of adjacent wave fronts in order to achieve a local increase in contrast in the plane of the wafer.

Off-axis exposure selects, in a targeted manner, particularly advantageous orders of diffraction for the structures that are respectively to be imaged. Multipole exposure, particularly in combination with off-axis exposure, selects particularly advantageous orders of diffraction and directions of diffraction relative to the mask or wafer surface. In this case, a dipole exposure, by way of example, is used to cause light to fall onto the mask only from a specific preferred direction. A direction-dependent exposure is present in the case of such multipole exposure since structures on the mask, depending on the geometrical arrangement of the dipole exposure with respect to the arrangement of the structures of the mask, are imaged differently in a first exposure direction than structures that lie in a second exposure direction.

The various RETs may also be combined on one mask depending on lithographic requirements.

Lithography may generally involve the situation arising in which, in the case of an exposure of a very bright plane, that is to say in the case of a small absorption area proportion in or else outside the exposure field on the mask, scattered light may lead locally to a considerable decrease in contrast between regions that are to be exposed and regions that are not to be exposed on the wafer. This decrease in contrast may lead to an untenable restriction of the process window for this exposure step.

Hitherto it has been attempted to solve this problem by using a contrast reversal of the wafer process, by way of example. However, this leads to enormous restrictions in the optimization of the wafer process implementation.

### SUMMARY OF THE INVENTION

In one aspect, the present invention provides a device and a method with which the contrast-reducing influence of scattered light can be reduced or avoided.

A lithography mask according to embodiments of the invention has at least one auxiliary structure for minimizing scattered light, the auxiliary structure essentially being arranged in a low-resolution exposure direction of the direction-dependent exposure device for the mask. The arrangement of the auxiliary structures in the low-resolution exposure direction enables the auxiliary structures to be fabricated in a simple manner without the auxiliary structures being printed on the wafer. An additional lithographic gray scale can be realized by means of the auxiliary structures.

In this case, it is advantageous if the direction-dependent exposure is effected by means of a dipole element, a quadrupole element, a multipole element and/or an annular element.

An advantageous configuration of at least one auxiliary structure is a line pattern, an uninterrupted line pattern, a dash-dotted line pattern and/or a dotted line pattern for producing a gray scale. These auxiliary structures can be fabricated in a simple manner.

In one aspect, the present invention discloses a lithography system having a lithography mask having a structure for the fabrication of semiconductor components, in particular memory components, for a direction-dependent exposure device. The mask features at least one auxiliary structure for minimizing scattered light. The auxiliary structure is essentially arranged in a low-resolution exposure direction of the direction-dependent exposure device for the mask. The direction-dependent exposure can be effected by means of a dipole element, a quadrupole element, a multipole element and/or an annular element. At least one auxiliary structure can be formed as a line pattern, as an interrupted line pattern, as a dashed-dotted line pattern and/or as a dotted line pattern for producing a gray scale.

In this case, it is advantageous if the exposure device has a dipole element, a quadrupole element and/or an annular element. The dipole element advantageously has two circular openings or two circle-segment-shaped openings.

The quadrupole element advantageously has four circular openings or four circle-segment-shaped openings.

### BRIEF DESCRIPTION OF THE DRAWINGS

The invention is explained in more detail below on the basis of a plurality of exemplary embodiments with reference to the figures of the drawings in which:

FIGS. 1a-c show a construction of a lithography system with direction-dependent exposure in accordance with the prior art (a, b), a desired structure on a wafer (c);

FIGS. 2a-b show a diagrammatic illustration of elements for producing a direction-dependent exposure;

FIG. 3 shows a diagrammatic illustration of a lithography mask according to a preferred embodiment of the invention.

The following reference numbers are associated with the figures:
1 auxiliary structure
2 main structure
5 light beam
10 mask
10a vertical mask
10b horizontal mask
11 dipole element (direction-dependent exposure device)
11a quadrupole element (direction-dependent exposure device)
11b annular element (direction-dependent exposure device)
12, 12a, 12b openings in dipole element
13 lens
20 wafer

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

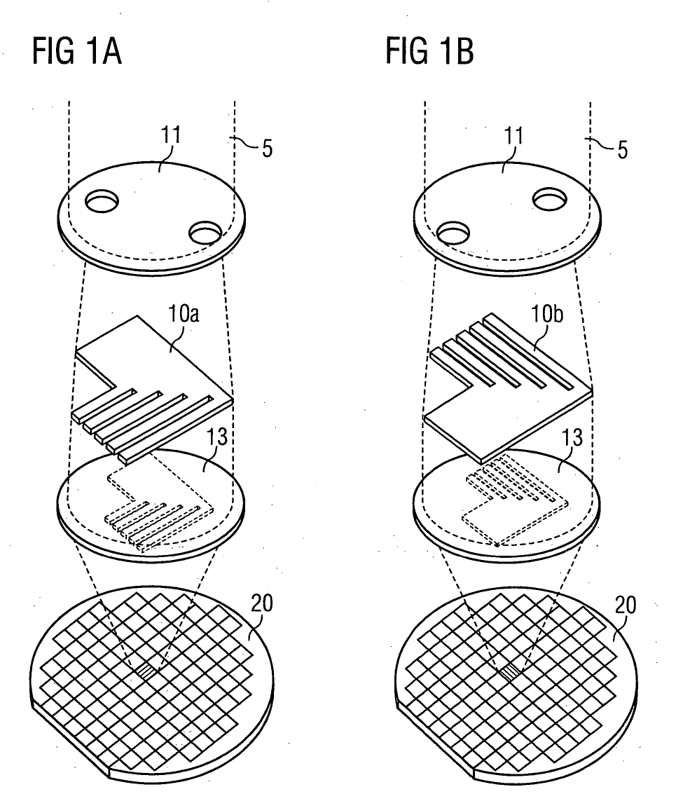

FIGS. 1a to 1c diagrammatically illustrate a lithography system known per se with a direction-dependent exposure device 11 (here a dipole element). The main structure 2 illustrated in FIG. 1c is thereby intended to be produced on a wafer 20.

A light beam 5 (e.g., having a wavelength of 193 nm) is radiated onto the dipole element 11. The dipole element 11 has two openings 12, which have the effect that optical elements located downstream in the beam path are irradiated at different angles. The openings 12 are formed as circular openings here, other geometries also being possible. The dipole element 11 here constitutes a direction-dependent exposure device.

A vertical mask 10a is irradiated by the beam altered by the dipole element 11. This vertical mask 10a is intended to image a first part of the desired main structure 2 via a lens 13 on the wafer 20. In this case, the part (line structure) of the vertical mask 10a that is to be imaged lies perpendicular to the connecting axis of the two openings 12 of the dipole element 11.

In order to complete the main structure 2 on the wafer, a horizontal mask 10b is subsequently used and the dipole element 11 is rotated through 90°. The structures (line structure) of the mask 10b that are to be imaged once again lie perpendicular to the connecting axis of the openings 12.

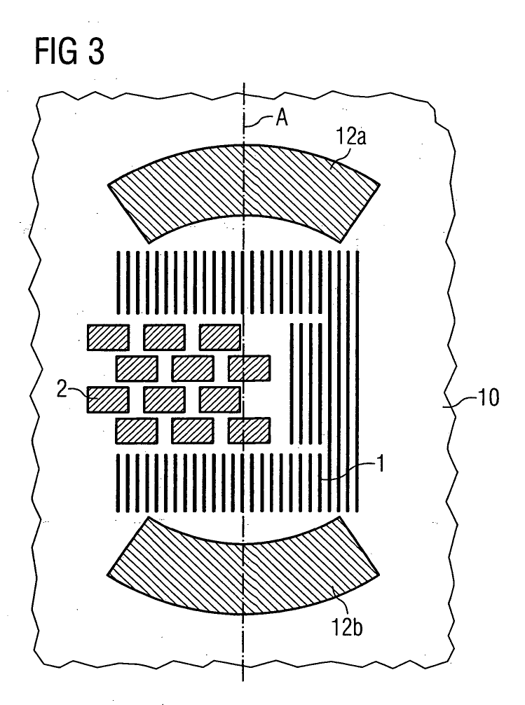

The main structure 2 is thus produced in two steps, the imaging properties of the direction-dependent exposure being utilized in each step. As an alternative, it is possible, given a suitable structure, to carry out a single exposure in order to utilize the direction-dependent properties (see e.g., FIG. 3).

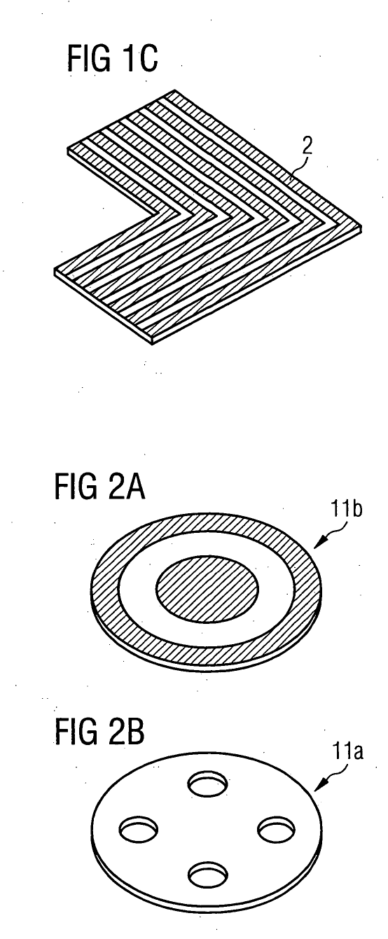

FIGS. 2a and 2b diagrammatically illustrate two alternative elements for producing a direction-dependent exposure: a quadrupole element 11a and an annular element 11b.

The preferred embodiment of the invention solves the problem that, in the case of large bright regions of a mask 10, the light also radiates into regions that are inherently to be kept dark.

An embodiment of a lithography mask 10 according to the invention is illustrated diagrammatically with reference to FIG. 3. FIG. 3 diagrammatically shows a main structure 2 (e.g., CB dots) on a mask 10, which is not illustrated in its entirety here. The openings 12a, 12b of a dipole element (not illustrated here) are illustrated in the projection into the plane of the mask 10. The openings 12a, 12b have the form of an annulus segment here.

The main extents of the main structures 2 lie perpendicular to the connecting axis A of the two openings 12a, 12b. This orientation of the main structures 2 relative to the connecting axis A characterizes the high-resolution lithography direction. This achieves the intended effect of multipole off-axis exposure being able to produce small main structures 2 on the wafer by means of the dipole element 11. In this case, exposure has to be effected only once here, unlike in the case of the example in accordance with FIG. 1.

According to embodiments of the invention, auxiliary structures 1 are arranged on the lithography mask 10, which auxiliary structures reduce or avoid the scattered light on the mask 10. In this case, the auxiliary structures 1 are arranged perpendicular to the high-resolution lithography direction of the dipole element 12, i.e., in the low-resolution lithography direction.

On account of their small dimensions and their orientation relative to the lithography direction, the auxiliary structures 1 are no longer resolved in the lithography step. The scattered light background can thus be reduced to an extent such that the local contrast between regions that are to be exposed and regions that are not to be exposed on the wafer, and thus the process window of the lithography step, are preserved or optimized. Through suitable orientation of the auxiliary structures 1, the latter can be made large enough that their fabrication on the mask is significantly simplified or even actually made possible in the first place.

By applying these non-resolving auxiliary structures 1 on the mask 10, it is possible to realize a gray scale for the wafer exposure step. If the auxiliary structures 1 were in this case located in the high-resolution direction of the lithography step, they would have to be so small on the mask that their fabrication would be extremely complicated or even impossible with the existing mask production installations. By rotating the auxiliary structures 1 in the low-resolution lithography direction, it is possible to achieve the same lithographic effect with significantly larger auxiliary structures 1 on the mask. These larger auxiliary structures 1 are significantly simpler to fabricate, or can actually be fabricated in the first place.

The embodiment of the invention is not restricted to the preferred exemplary embodiments specified above. Rather, a number of variants are conceivable which make use of the device according to the invention also in the case of embodiments of fundamentally different configuration.

1. A lithography mask having a structure for the fabrication of semiconductor components for a direction-dependent exposure device, the lithography mask comprising:
a mask substrate;
a plurality of main structures disposed over the mask substrate; and
at least one auxiliary structure disposed over the mask substrate, the at least one auxiliary structure for minimizing scattered light, the auxiliary structure essentially being arranged in a low-resolution exposure direction of the direction-dependent exposure device for the mask.

2. The lithography mask as claimed in claim 1, wherein the direction-dependent exposure is effected by means of a dipole element, a quadrupole element, a multipole element and/or an annular element.

3. The lithography mask as claimed in claim 2, wherein the direction-dependent exposure is effected by means of a dipole element.

4. The lithography mask as claimed in claim 2, wherein the direction-dependent exposure is effected by means of a quadrupole element.

5. The lithography mask as claimed in claim 2, wherein the direction-dependent exposure is effected by means of a multipole element.

6. The lithography mask as claimed in claim 2, wherein the direction-dependent exposure is effected by means of an annular element.

7. The lithography mask as claimed in claim 1, wherein the at least one auxiliary structure is formed as a line pattern, as an interrupted line pattern, as a dashed-dotted line pattern and/or as a dotted line pattern for producing a gray scale.

8. The lithography mask as claimed in claim 1, wherein the at least one auxiliary structure is formed as a line pattern.

9. The lithography mask as claimed in claim 1, wherein the at least one auxiliary structure is formed as an interrupted line pattern.

10. The lithography mask as claimed in claim 1, wherein the at least one auxiliary structure is formed as a dashed-dotted line pattern.

11. The lithography mask as claimed in claim 1, wherein the at least one auxiliary structure is formed as a dotted line pattern.

12. The lithography mask as claimed in claim 1, wherein the lithography mask includes a structure for the fabrication of semiconductor memory components.

13. A lithography system comprising:
a lithography mask that includes at least one auxiliary structure disposed over a mask substrate, the at least one auxiliary structure for minimizing scattered light, the auxiliary structure essentially being arranged in a low-resolution exposure direction of the direction-dependent exposure device for the mask; and
a direction-dependent exposure device configured to expose the lithography mask.

14. The lithography system as claimed in claim 13, wherein the exposure device includes a dipole element.

15. The lithography system as claimed in claim 14, wherein the dipole element includes two circular openings.

16. The lithography system as claimed in claim 14, wherein the dipole element includes two circle-segment-shaped openings.

17. The lithography system as claimed in claim 13, wherein the exposure device has a quadrupole element.

18. The lithography system as claimed in claim 17, wherein the quadrupole element has four circular openings.

19. The lithography system as claimed in claim 17, wherein the quadrupole element has four circle-segment-shaped openings.

20. The lithography system as claimed in claim 13, wherein the exposure device has an annular element.

21. A method of fabricating a semiconductor wafer, the method comprising:
providing a mask that includes a plurality of main structures and at least one auxiliary structure disposed over a mask substrate, the at least one auxiliary structure for minimizing scattered light, the auxiliary structure essentially being arranged in a low-resolution exposure direction of the direction-dependent exposure device for the mask;
providing a wafer with a light sensitive layer formed thereon;
transmitting a light beam through the mask and toward the wafer so that a structure of the mask is transferred into the light sensitive layer on the wafer.
